(19) United States
(12) Patent Application Publication
(10) Pub. No.: US 2005/0199996 A1
(43) Pub. Date: Sep. 15, 2005

(54) Two solder array structure with two high melting solder joints

(76) Inventor: Tony H. Ho, Hsinchu City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/796,084

(22) Filed: Mar. 10, 2004

(51) Int. Cl. H01L 21/44; H01L 21/48; H01L 21/50; H01L 23/053; H01L 23/12

(52) U.S. Cl. 257/700

(57) ABSTRACT

The present invention includes a semiconductor package that forms the array solder joints on the die surface and corresponding BGA substrate and PCB respectively. The life times of array solder joints are increased through the use of two sets of array joints. The top array comprises a plurality of high melting solder joints, while the bottom array comprises a plurality of high melting solder joints and low melting solder paste. The reflow temperature of SMT assembly is between the aforementioned high melting solder joints and low melting solder paste. In addition, each solder joint comprises a flat surface at its front edge.

### FIELD OF THE INVENTION

The present invention is related to an electronic package in general, and in particularly to an in-line process of PCB assembly using two sets of array solder joints.

### BACKGROUND OF THE INVENTION

As the wafer's manufacturing technology keeps on stepping forward, the traditional wire bonding process has no longer fitted into the needs of today's art. The design principle of “light, thin, short, and small” can be achieved through the use of array solder joints. Hence, the array solder joints of FC/BGA and Flip Chip (FC) have become the main streams of currently advanced package assembly. FC/BGA method which a semiconductor die is inverted in connecting with a top surface of BGA substrate first, then its bottom surface of BGA substrate is implemented with a PCB. While Flip Chip method that a semiconductor is inverted in connecting with a PCB directly. The life times of solder joints are intimately dependent on the stand-off of array solder joints. If the stand-off of solder joints is not big enough to resist the induced thermal stress exerted by reflow process, the underfill has to be added for reliability assurance. However, the addition of underfill will make repair work be more difficult, and become the bottleneck to its package assembly. Also, the solder pitch of solder joints has to be effectively reduced in order to accommodate more I/O onto the dice. Hence, how to increase the stand-off of solder array as well as to reduce the solder pitch have become two major issues for the criterion of package design. In Ho's patent U.S. Pat. No. 6,657,124B2, the package method using two sets of array solder joints had been proposed. Each solder array comprised a plurality of high melting solder joints and a plurality of low melting solder joints. The high melting solder joints which were mainly served as the pillars to sustain the stand-off of array solder joints and increased their life times. In this patent, the principle of two solder arrays is continually used but modified with different methods that are illustrated by the followings.

### OBJECTIVES AND SUMMARY OF THE INVENTION

The primary objective of present invention is to provide the solid connections between a semiconductor die and the PCB through the use of two sets of array solder joints. The top array comprises a plurality of high melting solder joints, while the bottom array comprises a plurality of high melting solder joints and low melting solder paste.

At connective interface, each solder array comprises two sets of melting solder points. The high melting solder joints are served as the pillars to maintain the stand-off. The solder joints of top array and correspondingly bottom array are attached together through the adhesion of solder paste, after reflow temperature had been cooled down to room temperature. The reflow temperature is between the aforesaid high melting solder joints and low melting solder paste.

Secondly, each solder joint comprises a flat surface at its front edge in order to facilitate the connections between a top array and correspondingly bottom array. In addition, the flat surface of bottom array comprises a concave middle. At bottom array, the flat surface of high melting solder joint is served as the solder pad in connecting with the solder joint of top array. The addition of underfill can be skipped that will make the repair work become very straightforward.

Thirdly, the flat surface of bottom array is designed to have 3% to 80% bigger than the flat surface of correspondingly top array so that the solder paste implemented in between the top array and bottom array can form the solid adhesions. Therefore, the solder pitch will have a chance to reduce below 0.3 mm in accommodating extensive I/O applications.

### BRIEF DESCRIPTION OF THE DRAWINGS

FIG. 1 shows the single structure that a high melting solder joint of top array is attached with a high melting solder joint of bottom array. Each solder joint comprises a flat surface at its front edge.

FIG. 2 shows the single structure that a high melting solder joint of top array is attached with a high melting solder joint of bottom array. The flat surface of bottom array comprises a concave middle.

FIG. 3 shows the flow chart that a semiconductor die is attached to a PCB through BGA substrate by using two sets of high melting solder joints.

FIG. 4 shows the flow chart that a semiconductor die is attached to a PCB directly through Flip Chip by using two sets of high melting solder joints.

### DETAILED DESCRIPTION OF THE INVETION

In regular SMT (Surface Mount Technology) process, the solder paste and low melting solder joints are melted at reflow stage. They will first collapse, melt into molten state, and are solidified through surface tension of solder pads in connecting a semiconductor die with a PCB. The stand-off of low melting solder joints will be reduced to 65% to 70% solder height of barrel ones compared to the solder height of originally circular ones. For the purpose of increasing the life times of solder joints by using two sets of array joints was proposed in Ho's patent U.S. Pat. No. 6,657,124B2. Each solder array comprised a plurality of high melting solder joints and a plurality of low melting solder joints. The high melting solder joints of top array were connected with their correspondingly high melting solder joints of bottom array, while the low melting solder joints of top array were connected with their correspondingly low melting solder joints of bottom array. The melting point of high melting solder joints was defined to have 20° C. higher than the reflow temperature at least, while the melting point of low melting solder joints was defined to have 20° C. lower than the reflow temperature at least. The high melting solder joints were served as the pillars to sustain the stand-off. The low melting solder joints were melted first and formed into the permanent hourglass-like shapes with good mechanical strength. However, there was a risk that the induced crack might be initiated at the middle part of hourglass-like solder joint where the stress concentration was reached a maximum.

The primary objective is to assure that there are solid adhesions between the solder joints of a top array and correspondingly bottom array. A plurality of embodiments is employed to illustrate the scope and characteristic of present invention.

First, the array solder joints of bottom array and top array are replaced with a plurality of high melting solder joints only. The connection of a top array with correspondingly bottom array is through the adhesion of solder paste. To facilitate the adhesion between a top array and correspondingly bottom array, each solder joint comprises a flat surface at its front edge in order to expand the contact area. Second, the flat surfaces of high melting solders located at bottom array are served as the solder pads, since they are not melted at reflow stage. Hence, the induced crack initiated at the middle part of hourglass-like solder joints will be eliminated.

Third, the flat surface of bottom array is designed to have 3% to 80% bigger than the flat surface of correspondingly top array. In addition, the flat surface of bottom array comprises a concave middle so that the extra solder paste won't flow out of the flat surface of bottom array as well as to contain as much solder paste as possible. Hence, the high melting solder joints of top array and bottom array can be intimately formed together through the adhesion of solder paste after reflow process.

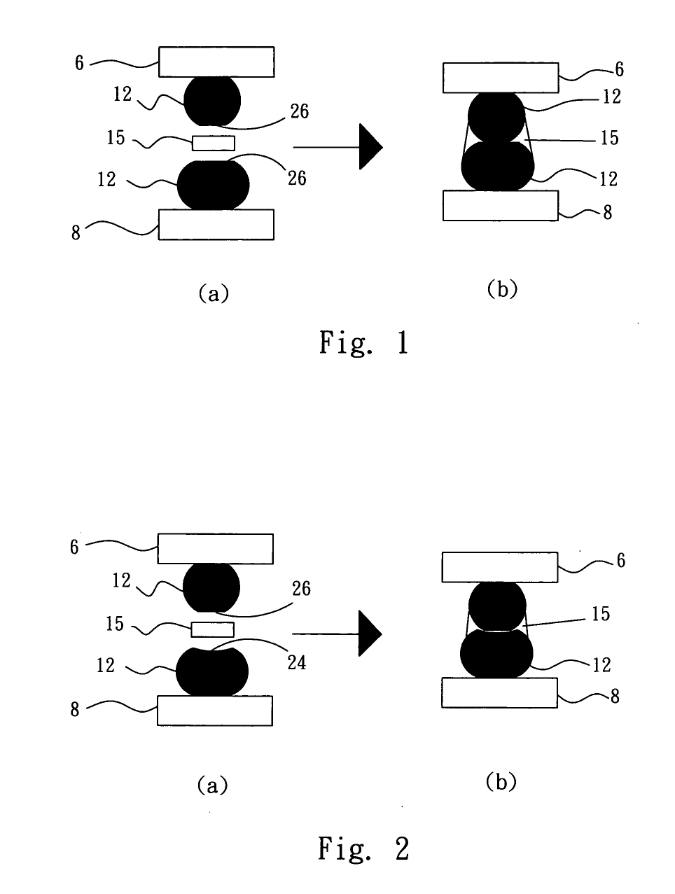

FIG. 1 shows the single structure that a high melting solder joint 12 of top array 6 is connected with a high melting solder 12 of bottom array 8. The top array 6 is either located on die surface or located on bottom surface of BGA substrate, while the bottom array 8 is either located on top surface of BGA substrate or located on the surface of PCB. Each solder joint comprises a flat surface 26 at its front edge. The flat surface 26 of top array 6 is 3% to 80% smaller than the flat surface 26 of bottom array 8. The flat surface 26 of bottom array 8 is served as the solder pad in connecting with the solder joint of top array 6. A thin solder paste 15 is implemented in between the top array 6 and bottom array 8. After reflow process, the high melting solder joint 12 of top array 6 and the high melting solder 12 of bottom array 8 is formed into the integral part together through the adhesion of solder paste 15.

FIG. 2 shows the single structure that a high melting solder joint 12 of top array 6 is connected with a high melting solder joint 12 of bottom array 8 too. As compared with FIG. 1, the flat surface 26 of bottom array 8 comprises a concave middle 24 in order to contain as much solder paste 15 as possible. In addition, the solder paste 15 won't flow off the flat surface 26 of bottom array 8. Hence, the high melting solder joints 12 of top array 6 and the high melting solder joints 12 of bottom array 8 is intimately formed into the integral part together.

The conventional package structures of FC/BGA and Flip Chip are illustrated with two sets of array solder joints. In FC/BGA structure, a semiconductor die is attached to a BGA substrate first, then the BGA substrate is attached with a PCB to complete the assembly. Multiple chips can be implemented onto the top surface of BGA substrate through the use of two sets of array solder joints. Hence, different functions of IC chips can be integrated into a single package that is so called the system in package (SIP) or named by system on chip (SOC). In Flip Chip structure, a semiconductor die is direct chip attachment (DCA) with a PCB. As compared with FC/BGA structure, because a BGA substrate which has the signal, power and ground lines embedded that is functioned as a specific PCB and belongs to a kind of PCB. In fact, the Flip Chip structure described above is identical with the structure that a semiconductor die is attached to the top surface of BGA substrate, if BGA substrate is considered as a kind of PCB.

(A) FC/BGA Structure

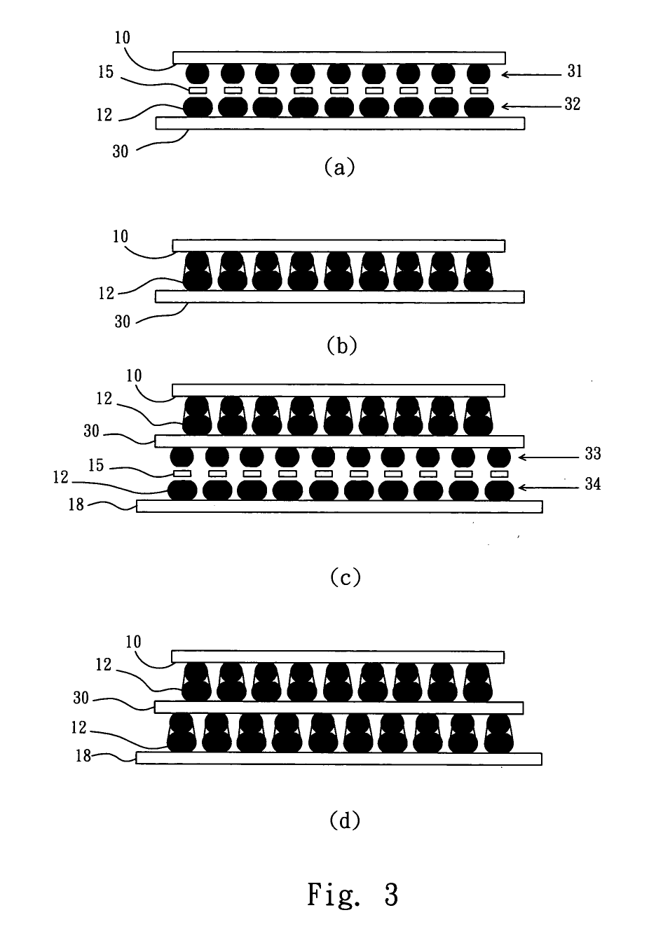

FIG. 3 shows the flow chart that a semiconductor die is attached to a PCB through BGA substrate. As shown in FIG. 3a, a first array 31 comprises a plurality of high melting solder joints 12 is implemented onto the die surface 10 and projecting downwardly. A second array 32 comprises a plurality of high melting solder joints 12 is implemented on the top surface of BGA substrate 30. A group of solder paste 15 is positioned in between the first array 31 and the second array 32. The solder paste 15 is placed on the flat surface of high melting solder joints 12 located at second array 32 first. The first array 31 is integral with the second array 32. The solder joints located on first array 31 are heading in correspondence with the solder paste 15 and the solder joints located on second array 32. After reflow process, the first array 31 is attached to the second array 32 as shown in FIG. 3b.

In FIG. 3c, a third array 33 comprises a plurality of high melting solder joints 12 is implemented with the bottom surface of BGA substrate 30 and projecting downwardly. A fourth array 34 that comprises a plurality of high melting solders 12 is implemented with a PCB 18. A group of solder paste 15 is positioned in between the third array 33 and the fourth array 34. The third array 33 is integral with the fourth array 34. The high melting solder joints 12 located on the third array 33 are heading in correspondence with the solder paste 15 and the high melting solder joints 12 located on the fourth array 34. After reflow process, the third array 33 is attached to the fourth array 34 as shown in FIG. 3d. Because the high melting solder joints 12 implemented on first array 31 and second array 32 need to pass the reflow process twice, the high melting solder joints 12 implemented on second array 32 and implemented on first array 31 have a higher or equal melting point than the melting point of high melting solder joints 12 implemented on fourth array 34. In addition, the high melting solder joints 12 implemented on second array 32 and implemented on first array 31 have a higher or equal melting point than the melting point of high melting solder joints 12 implemented on fourth array 33.

(B) Flip Chip Structure

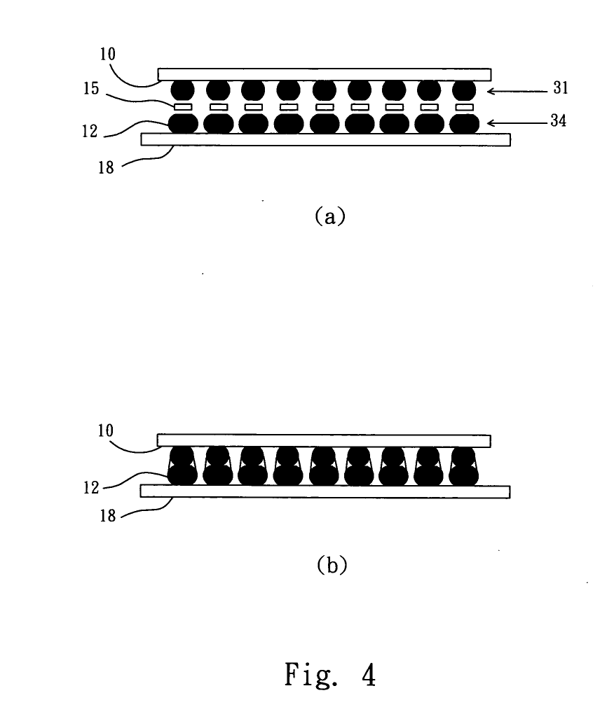

FIG. 4 shows the flow chart that a semiconductor die is attached to a PCB directly. As shown in FIG. 4a, a first array 31 comprises a plurality of high melting solder joints 12 is implemented onto a die surface 10 and projecting downwardly. A fourth array 34 comprises a plurality of high melting solders 12 is implemented with a PCB 18. A group of solder paste 15 is positioned between the first array 31 and the fourth array 34. The solder paste 15 is placed on the flat surface of high melting solder joints 12 located at fourth array 34 first. The first array 31 is integral with the fourth array 34. The solder joints located on first array 31 are heading in correspondence with the solder paste 15 and the solder joints located on fourth array 34. After reflow process, they are intimately formed into the integral part together as shown in FIG. 4b.

1. A semiconductor packaging structure comprising:
an electrically substrate having a top surface and a bottom surface;
a semiconductor die uplying said top surface;
a first array comprising a first plurality of solder joints, mounted on said die surface and projecting downwardly;
a second array comprising a second plurality of solder joints, mounted on said top surface, integral with said first array, therefrom, connecting said die surface and said top surface, and said solder joint of said second array comprising a flat surface at its front edge; and
a group of solder paste located between said first array and said second array, therefrom, said first plurality of solder joints and said second plurality of solder joints having a higher melting point than said solder paste.

2. The structure described in claim 1 wherein said first array integral with said second array, at integral process, predetermined the shape of solder joints, said first plurality of solder joints and said second plurality of solder joints were not melted, and said solder paste were melted.

3. The structure described in claim 1 further comprising:
a print circuit board underlying said substrate;
a third array comprising a third plurality of solder joints, mounted on said bottom surface and projecting downwardly;
a fourth array comprising a fourth plurality of solder joints, mounted on said print circuit board, integral with said third array, therefrom, connecting said bottom surface and print circuit board, and said solder joint of said fourth array comprising said flat surface at its front edge; and
a group of solder paste located between said third array and said fourth array, therefrom, said third plurality of solder joints and said fourth plurality of solder joints having a higher melting point than said solder paste.

4. The structure described in claim 3 wherein said third array integral with said fourth array, at integral process, predetermined the shape of solder joints, said third plurality of solder joints and said fourth plurality of solder joints were not melted, and said solder paste were melted.

5. The structure described in claim 1 wherein said solder joint located on said first array comprises said flat surface at its front edge.

6. The structure described in claim 1 wherein said solder joint located on said third array comprises said flat surface at its front edge.

7. The structure described in claim 1 wherein said flat surface of said second plurality of solder joints comprises a concave middle.

8. The structure described in claim 1 wherein said flat surface of said fourth plurality of solder joints comprises a concave middle.

9. The structure described in claim 1 wherein said flat surface implemented on said first plurality of solder joints is 3% to 80% smaller than said flat surface implemented on said second plurality of solder joints.

10. The structure described in claim 1 wherein said flat surface implemented on said third plurality of solder joints is 3% to 80% smaller than said flat surface implemented on said fourth plurality of solder joints.

11. The structure described in claim 1 wherein said semiconductor package had been assembled, said first plurality of solder joints and said second plurality of solder joints were not melted, and said solder paste were melted.

12. The structure described in claim 1 wherein said semiconductor package had been assembled, said third plurality of solder joints and said fourth plurality of solder joints were not melted, and said solder paste were melted.

13. The structure described in claim 1 wherein said first plurality of solder joints and said second plurality of solder joints having a higher or equal melting point than said fourth plurality of solder joints.

14. The structure described in claim 1 wherein said first plurality of solder joints and said second plurality of solder joints having a higher or equal melting point than said third plurality of solder joints.

15. The structure described in claim 1 wherein the number of semiconductor dies is at least two.

16. The structure described in claim 1 wherein said solder joints implemented on said die surface are heading in correspondence with said solder joints implemented on said top surface.

17. The structure described in claim 1 wherein said solder joints implemented on said bottom surface are heading in correspondence with said solder joints implemented on said print circuit board.

18. A semiconductor packaging structure comprising:
at lease one semiconductor die;
a print circuit board underlying said dies;
a first array comprising said first plurality of solder joints, mounted on said die surface and projecting downwardly;
a fourth array comprising said fourth plurality of solder joints, mounted on said print circuit board, integral with said first array, therefrom, connecting said die surface and said print circuit board; and
a group of solder paste located between said first array and said and said fourth array, therefrom, said first plurality of solder joints and said fourth plurality of solder joints having a higher melting point than said solder paste.

19. The structure described in claim 18 wherein said first array integral with said fourth array, at integral process, predetermined the shape of solder joints, said first plurality of solder joints and said fourth plurality of solder joints were not melted, and said solder paste were melted.
